(19) United States
(12) Patent Application Publication
(10) Pub. No.: US 2009/0266398 A1
(43) Pub. Date: Oct. 29, 2009

(54) Method and Apparatus to Form Back Contacts to Flexible CIGS Solar Cells

(76) Inventors: Burak Metin, Milpitas, CA (US); Mukundan Narasimhan, San Jose, CA (US); Mustafa Pinarbasi, Morgan Hill, CA (US); Bulent M. Basol, Manhattan Beach, CA (US)

Correspondence Address: PILLSBURY WINTHROP SHAW PITTMAN LLP, P.O. BOX 10500, MCLEAN, VA, 22102, US

(21) Appl. No.: 12/111,161

(22) Filed: Apr. 28, 2008

(51) Int. Cl. H01L 31/042

(52) U.S. Cl. 136/244

(57) ABSTRACT

An apparatus for and a method of interconnecting at least two solar cells using contact areas which are formed on the conductive substrates of the solar cells is described. The contact areas are formed by a material removal process which removes high resistance surface layers of the conductive substrates at the contact areas. A stringing process serially interconnects the solar cells by connecting each contact area that is cleared of high resistance surface layer to the terminal of one of the adjacent solar cells.

### BACKGROUND

1. Field of the Invention

The present invention generally relates to thin film solar cell fabrication and integration, more particularly, to techniques for interconnecting Group IBIIIAVIA based thin film solar cells to form photovoltaic modules.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0≦y≦1 and k is approximately 2, have already been employed in solar cell structures that yielded conversion efficiencies approaching 20%. It should be noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a conventional Group IBIIIAVIA compound photovoltaic cell such as a Cu(In,Ga,Al)(S,Se,Te)₂ thin film solar cell is shown in FIG. 1. A photovoltaic cell 10 is fabricated on a substrate 11, such as a sheet of glass, a sheet of metal, an insulating foil or web, or a conductive foil or web. An absorber film 12, which comprises a material in the family of Cu(In,Ga,Al)(S,Se,Te)₂, is grown over a conductive layer 13 or contact layer, which is previously deposited on the substrate 11 and which acts as the electrical contact to the device. The substrate 11 and the conductive layer 13 form a base 20 on which the absorber film 12 is formed. Various conductive layers comprising Mo, Ta, W, Ti, and their nitrides have been used in the solar cell structure of FIG. 1. If the substrate itself is a properly selected conductive material, it is possible not to use the conductive layer 13, since the substrate 11 may then be used as the ohmic contact to the device. After the absorber film 12 is grown, a transparent layer 14 such as a CdS, ZnO, CdS/ZnO or CdS/ZnO/ITO stack is formed on the absorber film 12. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side.

If the substrate 11 of the CIGS(S) type cell shown in FIG. 1 is a metallic foil, then under illumination, a positive voltage develops on the substrate 11 with respect to the transparent layer 14. In other words, an electrical wire (not shown) that may be attached to the substrate 11 would constitute the (+) terminal of the solar cell 10 and a lead (not shown) that may be connected to the transparent layer 14 (or to a metallic grid that may be deposited on the transparent layer 14) would constitute the (−) terminal of the solar cell.

After fabrication, individual solar cells are typically assembled into solar cell circuits by interconnecting them in series electrically, i.e. by connecting the (+) terminal of one cell to the (−) terminal of a neighboring cell. This way the total voltage of the solar cell circuit is increased. The solar cell circuit is then laminated into a protective package to form a photovoltaic module.

For a device structure of FIG. 1, if the substrate 11 is a conductive metallic foil, series interconnection of cells may be carried out by connecting the substrate 11 at the back or un-illuminated side of one particular cell to the busbar of a finger pattern (not shown) at the front or illuminated side of the adjacent cell. A common industry practice is to use conductive wires, preferably in the form of strips of flat conductors or ribbons to interconnect a plurality of solar cells to form first a circuit and then a module as described before. Such ribbons are typically made of copper coated with tin and/or silver. Ribbons are attached to the front and back sides of the cells in the module structure by means of suitable soldering materials or conductive adhesives. In general, the soldering material is applied to the substrate and the busbar surfaces along with a flux and then the Cu ribbons are brought in physical contact with the solder and heat is applied to form physical and electrical bond between the substrate and the ribbon and/or between the busbar and the ribbon.

Although such prior art methods of interconnecting individual solar cells have been yielding good results for interconnecting Si solar cells where both the top and the bottom of the cell has screen printed silver-based busbars or contacts, the same approach has provided less than satisfactory results with regard to the quality of the ohmic contacts established between the metal substrates and the ribbons. Ohmic contacts between busbars and ribbons are of high quality since busbars contain Ag. However, in thin film structures such as the one shown in FIG. 1 the bottom electrical contact needs to be made directly on the metallic substrate using a ribbon and a conductive adhesive to attach the ribbon on the metallic surface of the substrate. Because of the processing techniques of the metal foil based CIGS solar cells, back surface of the metal foil is often coated with unwanted material films such as selenides which may form during the selenization process, and (CdS) cadmium sulfide film formed during the cadmium sulfide deposition process. Furthermore metallic foil surfaces are also susceptible to various forms of oxidation which form unwanted high resistance films on the substrate surfaces. It should be noted that manufacturing of thin metallic foils such as 25-100 um thick stainless steel foils employs high temperature rolling steps which leave the surface of these foils with non-conductive films, such as oxidation products. Such surface layers not only form a high resistivity film between the ribbon contact and the substrate but also make it difficult to attach a ribbon to the substrate. When cells are integrated into modules, such high resistance contacts lower the overall efficiency of the modules and reduce their reliability because non-ohmic contacts deteriorate in time.

From the foregoing, there is a need in the thin film solar cell manufacturing industry for improved interconnection methods that retain desired efficiency characteristics of manufactured solar cells.

### SUMMARY OF THE INVENTION

Present invention provides a method and apparatus for pre-treating the back surface of the solar cells having metallic substrates before interconnecting the solar cells for forming modules.

### BRIEF DESCRIPTION OF THE DRAWINGS

FIG. 1 is a side schematic view of a solar cell;

FIG. 2A is a side schematic cross sectional view of two solar cells taken along the line 2A-2A in FIG. 2B, wherein the solar cells have been interconnected using an embodiment of a process of the present invention;

FIG. 2B is top schematic view of the solar cells shown in FIG. 2A;

FIG. 3 is a schematic view of an embodiment of a system of the present invention;

FIG. 4A is a schematic view of an embodiment of a roll to roll system of the present invention;

FIG. 4B is a schematic top view of a continuous flexible workpiece to process in the roll to roll system shown in FIG. 4A; and

FIG. 4C is a schematic cross sectional view of a treating station of the roll to roll system taken along the line 2C-2C in FIG. 4A.

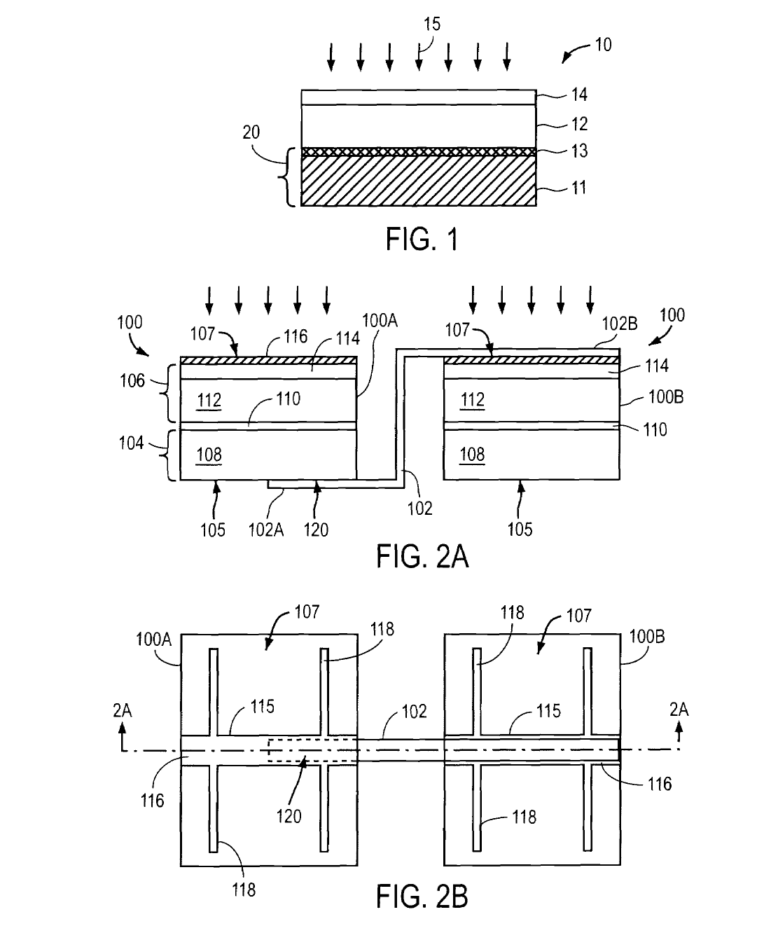

### DETAILED DESCRIPTION OF THE INVENTION

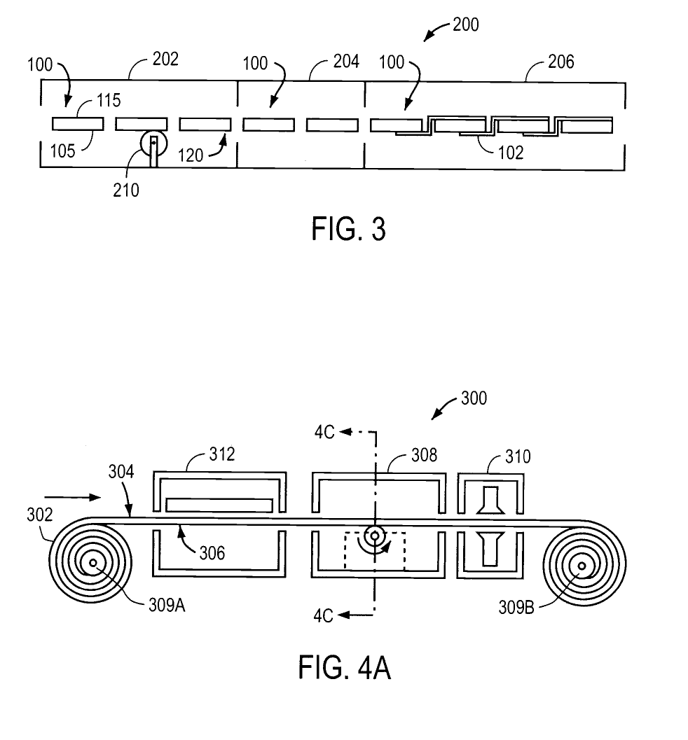

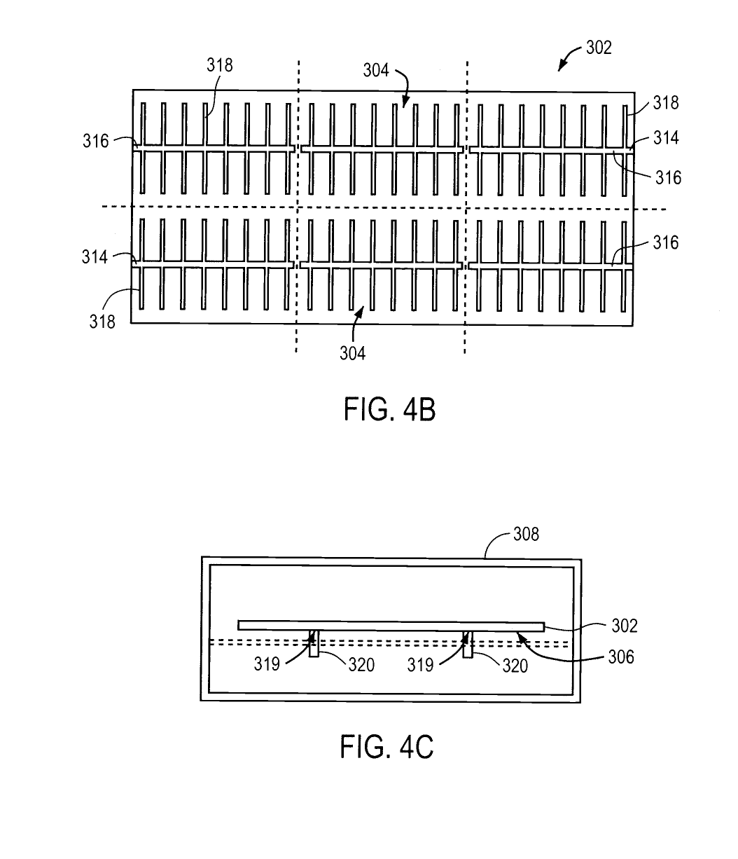

The present invention provides a method and apparatus for treating back surface of the solar cells having metallic substrates before interconnecting the solar cells for forming circuits and modules. The invention will be described using an interconnection process or stringing process for preferably thin film CIGS solar cells formed on flexible metallic foil substrates. The treatment method is applied to at least a portion of a back surface of the solar cells, i.e., substrate surface, before establishing electrical contacts to such surfaces. In one embodiment, the treatment process comprises mechanical abrasion and removal of at least a portion of an unwanted non-conductive material film from the substrate surface of the solar cell. As described in the background section, such unwanted material films may be formed on the back surface during selenization, CdS deposition and/or surface oxidation of the metallic substrate surface. In the following, FIGS. 2A-3 are used to describe an embodiment of the process of the present invention which employs individual solar cells. FIGS. 4A-4C are used to describe another embodiment using a roll-to-roll process to implement the present invention.

FIGS. 2A and 2B show exemplary solar cells 100 such as a first solar cell 100A and a second solar cell 100B which are interconnected by a conductive lead 102, or interconnect, using the process of the present invention. Although the process is exemplified using two solar cells, by using the interconnecting or stringing process of the present invention a plurality of solar cells may be interconnected. The conductive lead may be a strip of metal, preferably a conductive ribbon made of copper or any another conductor. Each solar cell 100 comprises a base portion 104 having a back surface 105 and a front portion 106 having a front surface 107. The base portion 104 includes a substrate 108 and a contact layer 110 formed on the substrate. For this embodiment, a preferred substrate material may be a metallic material such as stainless steel, aluminum (Al) or the like. An exemplary contact layer material may be molybdenum (Mo). The front portion 106 may comprise an absorber layer 112, such as a CIGS absorber layer which is formed on the contact layer 110, and a transparent layer 114, such as a buffer-layer/TCO stack, formed on the absorber layer where TCO stands for transparent conductive oxide. An exemplary buffer layer may be a (Cd,Zn)S layer. An exemplary TCO layer may be a ZnO layer, an indium tin oxide (ITO) layer or a stack comprising both ZnO and ITO. A terminal 115, or a finger pattern, including a busbar 116 and conductive fingers 118 may be formed over the front surface 107 as shown in FIG. 2B.

The conductive lead 102 electrically connects a contact area 120 formed on the back side 105 of the solar cell 100A to the terminal 115 of the solar cell 100B. Of course, another contact area may also be formed on the back side of the solar cell 100B to connect the solar cell 100B to the next solar cell (not shown) and so on, in a multiple solar cell stringing scheme. The contact area 120 is formed on the back surface 105 of the solar cell 100A by treating at least a portion of the back surface 105 of the substrate 108. The treatment process is a material removal process which may employ mechanical, chemical, or electrochemical techniques. In the preferred embodiment, the material removal may be performed using mechanical means such as mechanical brushing or sanding and the like. The treatment process removes at least a portion of the unwanted material layers, such as oxides, selenides or CdS and others, from the back surface 105 and exposes the fresh substrate material itself, thereby forming a contact area substantially free from high resistance species such as oxides, sulfides and selenides. This freshly exposed substrate portion provides a secure bonding location on the substrate for the conductive lead. In this respect the contact area 120 may be limited to a location on the back surface 105 of the solar cell 100A, which is near the solar cell 100B, as shown in FIGS. 2A and 2B. Alternatively the contact area may be formed as a strip extending across the back surface and aligned with the projection of the busbar. Alternately the contact area may be formed to cover the entire back surface.

During the stringing process, a first end 102A of the conductive lead 102 is attached to the contact location 120. A bonding material may be applied to at least one of the contact area and the surface of the first end 102 before attaching the conductive lead to the contact area. Similarly, a second end 102B of the conductive lead 102 is attached to a location on the busbar 116 of the solar cell 100B using the bonding material. The bonding material may be a conductive adhesive such as Ag-filled adhesive, solder material or the like. Depending on the nature of the bonding material, appropriate process steps, such as application of heat and pressure, are also carried out to bond the ends of the conductive lead to the cells.

FIG. 3 shows an embodiment of a system 200 to implement above described process. The system 200 includes a substrate treating station 202, a cleaning station 204 and a stringing station. A conventional workpiece handling and moving mechanism (not shown) may hold and move solar cells 100 in succession through the stations during the process. The solar cells 100 may include the structural components of the solar cells 100A and 100B shown in FIGS. 2A-2B. However the solar cells are simplified to show the back surface 105 or the substrate surface and the terminal 115 located on top of the solar cells 100. The substrate treating station 202 may include surface abrasion or surface material removal means such as rollers or wheels having abrasive surfaces, sanders, polishers or the like, which may be used to remove material from at least a portion of the back surface 105, thereby electrically activating it. In one embodiment, solar cells 100 entering the substrate treating station may be moved over one or more abrasive roller(s) 210. Alternately, abrasive roller(s) may be moved towards and contacted to the back surface 105. The abrasive roller 210 may continuously or intermittently touch and remove material from the back surface and thereby form the contact areas 120 as described above. The cleaning station 204 may include cleaning means such as vacuum suction systems, brushes, and adhesive rollers to remove particles and dust from the contact area, substrate, terminal and the other parts of the solar cells. It should be noted that it is possible to merge the treating 202 and the cleaning stations 204 in one location, in which case cleaning may be carried out as the surface abrasion is performed. This way, particles forming as a result of the treating process are immediately removed from the surface of the solar cell. The stringing station 206 may include means for attaching the conductive leads to the contact areas and the terminals of the solar cells to interconnect them as in the manner described above. The stringing station may typically contain means to dispense the bonding material such as Ag-filled adhesive, means to cut and place ribbons over the dispensed adhesive, means to press the ribbons against the solar cell surface and means to heat the strings formed through interconnecting to cure the conductive adhesive.

FIG. 4A shows a roll to roll system 300 to conduct the process of the present invention on a continuous flexible workpiece 302 which is exemplified in FIG. 4B. The continuous workpiece 302 comprises a large scale solar cell structure formed on a large substrate so that it can be later cut into individual solar cells similar to the ones shown in FIGS. 2A-2B before a stringing process. Therefore, a front surface 304 of the continuous workpiece 302 is the surface of a transparent conductive layer, and a back surface 306 is the back surface of a substrate, preferably a metallic substrate such as stainless steel. In the roll to roll processes of the present invention, above described contact areas are formed on the back surface 306 of the continuous workpiece before the cutting of the continuous workpiece.

The system 300 may comprise a treating station 308 and a cleaning station 310. Optionally, a terminal forming station 312 may be added to the system 300 to deposit terminal structures on the solar cell structure before the contact areas are formed on the back surface. During the process, a moving mechanism (not shown) may supply the continuous workpiece 302 from a supply roll 309A and advance through the stations. The processed continuous flexible workpiece is taken up from the cleaning station 206 and wrapped around a receiving roll 309B.

Referring to FIGS. 4A-4B, at a first stage of the roll to roll process, terminal structures 314 are formed on the front surface 304 of the continuous workpiece 302, preferably using a screen printing process. FIG. 4B shows the front surface in top view after forming the terminal structures 314. The terminal structures 314 include busbar lines 316 and conductive fingers 318 that are configured in a fishbone design. Dotted lines depict location of each individual cell which will be cut out from the continuous workpiece after the process of the present invention.

Referring to FIGS. 4A-4C, after forming the terminal structures 314, the continuous workpiece 302 is advanced into the treating station 308 to form contact areas 319 on the back surface 306 of the continuous workpiece 302. The contact areas may be formed by contacting a material remover 320 such as an abrasive roller, to the back surface, and thereby removing at least a part of the non-conductive material film from the substrate of the continuous workpiece. FIG. 4C, shows a cross section of the treating station 308, where material removers 320 form cleaned conductive areas as two strips extending on the back surface. The contact areas 319 are aligned with the busbar lines 316 to enable solar cells to be interconnected as shown in FIGS. 2A-2B. After the treating process the continuous workpiece is advanced into a cleaning station to remove particles and dust formed during the previous process steps and wrapped around the receiving roller 309B. In the following process steps, the workpiece with contact areas may be cut into individual solar cells in a cutting system including a cutter. Individual solar cells with contact areas are then interconnected in a stringing tool.

Although the present invention is described with respect to certain preferred embodiments, modifications thereto will be apparent to those skilled in the art.

We claim:

1. A method of electrically interconnecting first and second solar cells fabricated on conductive substrates covered with a non-conductive film, comprising:
forming a contact area on the conductive substrate of the first solar cell using a material removal process, wherein the material removal process removes at least a portion of the non-conductive film at the contact area;
attaching an end of a conductive lead to the contact area; and
electrically interconnecting the first solar cell to the second solar cell by attaching another end of the conductive lead to a terminal on top of the second solar cell.

2. The method of claim 1, wherein the step of forming the contact area comprises applying a mechanical material removal process to a back surface of the conductive substrate to remove the portion of the non-conductive film.

3. The method of claim 2, wherein the mechanical material removal comprises at least one of brushing, sanding, abrading and polishing.

4. The method of claim 2, wherein attaching the conductive lead comprises:
applying a conductive bonding material to the contact area; and
attaching the end of the conductive lead to the contact area using the conductive bonding material.

5. The method of claim 4, wherein the conductive bonding material is a conductive adhesive comprising silver.

6. The method of claim 5 further comprising applying heat and pressure to the contact area after the steps of applying and attaching.

7. The method of claim 2 further comprising the step of cleaning the contact area after the step of forming the contact area.

8. The method of claim 2, wherein the conductive substrate comprises stainless steel.

9. The method of claim 6, the conductive substrate comprises stainless steel.

10. The method of claim 9, wherein the conductive lead comprises copper.

11. The method of claim 9, wherein the terminal includes a busbar and conductive fingers, and wherein the other end of the conductive lead is connected to the busbar of the terminal.

12. A system for interconnecting a plurality of solar cells, comprising:
a carrier for supplying the plurality of solar cells in succession, each cell having a conductive substrate with an exposed surface on a back side and a terminal on a front side, the exposed surface comprising a non-conductive film;
a material remover to remove at least a portion of the non-conductive film of each cell to form a contact area on the exposed surface of the conductive substrate of each cell; and
a stringing machine to serially interconnect the solar cells by electrically connecting each contact area to the terminal of one of the adjacent solar cells.

13. The system of claim 12 further comprising a cleaner to clean the solar cells after removing the portion of the non-conductive film.

14. The system of claim 13, wherein the material remover and the cleaner are integrated so that dust and particles produced by the material remover are concurrently removed from the contact area by the cleaner.

15. The system of claim 14, wherein the material remover is a mechanical material remover comprising at least one of a brush, a sander and a polisher.

16. The system of claim 15, wherein the cleaner is a vacuum cleaner that removes the particles and dust produced by the material remover.

17. The system of claim 15, wherein the cleaner is a sticky roller that removes the particles and dust produced by the material remover.

18. A system including a capability for forming contact areas for use in electrically interconnecting a plurality of solar cells, comprising:
a moving mechanism for supplying a continuous flexible workpiece into the system, the continuous flexible workpiece including a continuous conductive substrate having a plurality of solar cells disposed thereon such that a back side of the continuous conductive substrate is covered with a non-conductive film;
a material removing station provided in the section of the system to remove a portion of the non-conductive film from the conductive substrate to form contact areas at locations corresponding respectively to each of the plurality of solar cells; and
a cleaning station to clean the continuous flexible workpiece after removing the non-conductive film from the conductive substrate.

19. The system of claim 18, further comprising a terminal forming station to form terminal structures on a front side of the continuous flexible workpiece before the material removing station, wherein each terminal structure corresponding to one of the plurality of solar cells.

20. The system of claim 19, wherein the terminal forming station is a screen printing station comprising a screen printing sub-station where each terminal structure is deposited on the front side of the continuous flexible workpiece and an annealing sub-station where the terminal structure is thermally cured.

21. The system of claim 20, further comprising a loading station with a feeding reel to supply the continuous flexible workpiece from the feeding reel into the screen printing station.

22. The system of claim 21 further comprising an unloading station with a receiving reel to receive and roll up the continuous flexible workpiece after it exits the cleaning station.

23. The system of claim 22, wherein the material removing station has a material remover comprising at least one of a brush, a sander and a polisher.

24. The system of claim 21 further comprising a cutting tool to cut the continuous flexible workpiece into the plurality of solar cells after the continuous flexible workpiece exits the cleaning station.

25. The system of claim 24 further comprising a stringing station to repeatedly electrically connect the contact area of one of the plurality of solar cells to the terminal of one adjacent other of the plurality of solar cells to obtain a string of solar cells.

26. The system of claim 18 further comprising an unloading station with a receiving reel to receive and roll up the continuous flexible workpiece after it exits the cleaning station.

27. The system of claim 18, wherein the material removing station has a material remover comprising at least one of a brush, a sander and a polisher.

28. The system of claim 27 further comprising a cutting tool to cut the continuous flexible workpiece into the plurality of solar cells after the continuous flexible workpiece exits the cleaning station.

29. The system of claim 28 further comprising a stringing station to repeatedly electrically connect the contact area of one of the plurality of solar cells to the terminal of one adjacent other of the plurality of solar cells to obtain a string of solar cells.

30. The system of claim 29, wherein the material removing station and the cleaning station are part of a material removal and cleaning chamber so that the dust and the particles produced in the material removing station are concurrently removed from the continuous flexible workpiece.

31. The system of claim 18 further comprising a cutting tool to cut the continuous flexible workpiece into the plurality of solar cells after the continuous flexible workpiece exits the cleaning station.

32. The system of claim 31 further comprising a stringing station to repeatedly electrically connect the contact area of one of the plurality of solar cells to the terminal of one adjacent other of the plurality of solar cells to obtain a string of solar cells.
